(19) United States
(12) Patent Application Publication
(10) Pub. No.: US 2014/0312489 A1
(43) Pub. Date: Oct. 23, 2014

(54) FLIP-CHIP SEMICONDUCTOR PACKAGE

(71) Applicant: Samsung Electronics Co., Ltd., Suwon-si (KR)

(72) Inventors: HO-HYEUK IM, Seoul (KR); JONG-KOOK KIM, Hwaseong-si (KR); SU-MIN PARK, Ansan-si (KR)

(73) Assignee: Samsung Electronics Co., Ltd., Suwon-si (KR)

(21) Appl. No.: 14/155,697

(22) Filed: Jan. 15, 2014

(30) Foreign Application Priority Data
Apr. 17, 2013 (KR) 10-2013-0042390

(51) Int. Cl. H01L 23/00

(52) U.S. Cl. CPC H01L 24/14; H01L 24/06; H01L 24/03
USPC 257/737; 174/261; 427/58

(57) ABSTRACT

A flip-chip semiconductor package is provided that includes a semiconductor chip, a package substrate having a chip attachment surface on which bond sites are formed, and bumps attached to an active surface of the semiconductor chip and bonded to the bond sites, wherein the bond sites are radially arranged around a middle portion of the package substrate.

### CROSS-REFERENCE TO RELATED APPLICATIONS

This application claims the benefit of priority under 35 U.S.C. §119 to Korean Patent Application No. 10-2013-0042390, filed on Apr. 17, 2013, the content of which is incorporated herein in its entirety by reference.

### BACKGROUND

1. Field

Embodiments of the inventive concept relate to a package substrate having a semiconductor chip mounted through a bump thereon, a flip-chip semiconductor package including the package substrate, and a semiconductor module, an electronic circuit board, and an electronic system, each including the flip-chip semiconductor package.

2. Description of the Related Art

The trend in semiconductor packages used in electronic devices is toward smaller sizes and thicknesses. Accordingly, a method of interconnecting a semiconductor chip to a package substrate through flip-chip bonding has been suggested in order to realize a high density, a high capacity, and a high speed performance while minimizing a mounting area and a thickness of the semiconductor package.

### SUMMARY

The present general inventive concept provides a flip-chip semiconductor package configured to prevent a bump from being deviated from a bond site due to thermal expansion/shrinkage of a package substrate.

The present general inventive concept also provides a package substrate configured to prevent a bump from being deviated from a bond site due to thermal expansion/shrinkage.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a flip-chip semiconductor package that includes a semiconductor chip, a package substrate, and bumps. The package substrate may have a chip attachment surface on which bond sites are formed. The bumps may be attached to an active surface of the semiconductor chip and may be bonded to the bond sites. The bond sites may be radially arranged around a middle portion of the package substrate.

In an example embodiment, the flip-chip semiconductor package may further include conductive leads formed on the chip attachment surface of the package substrate. The bond sites may exist on the conductive leads.

In an example embodiment, the flip-chip semiconductor package may further include a solder mask layer formed on the chip attachment surface of the package substrate. The solder mask layer may have openings formed at the bond sites.

In an example embodiment, the bond sites may include a bond site, disposed at the middle portion of the package substrate, that may not come into contact with the solder mask layer.

In an example embodiment, the bond sites may include bond sites, arranged in a vertical direction along the middle portion of the package substrate, that may not come into contact with the solder mask layer.

In an example embodiment, a cross-sectional length of each bond site at a first distance in a horizontal direction from the middle portion is longer than a cross-sectional length of each bond site at a second distance in the horizontal direction from the middle portion, the first distance greater than the second distance.

In an example embodiment, the bond sites include a bond site, located at a center area of the package substrate, that has a cross-sectional length longer than cross-sectional lengths of other bond sites disposed on a same line as the bond site located at the center area of the package substrate.

In an example embodiment, at least one of the bumps may be in contact with a sidewall of the bond site.

In an example embodiment, at least one of the bumps may be in contact with an upper surface of the bond site except for a sidewall of the bond site.

The foregoing and/or other features and utilities of the present general inventive concept may also be achieved by providing a package substrate that has bond sites formed on a chip attachment surface thereof. The bond sites may be radially arranged around a middle portion of the package substrate.

In an example embodiment, the package substrate may further include conductive leads formed on the chip attachment surface of the package substrate. The bond sites may exist on the conductive leads.

In an example embodiment, the package substrate may further include a solder mask layer formed on the chip attachment surface of the package substrate. The solder mask layer may have openings formed at the bond sites.

In an example embodiment, the bond sites may include bond sites, arranged in a vertical direction along the middle portion of the package substrate, that do not come into contact with the solder mask layer.

In an example embodiment, a cross-sectional length of each bond site at a first distance in a horizontal direction from the middle portion may be longer than a cross-sectional length of each bond site at a second distance in the horizontal direction from the middle portion. The first distance may be greater than the second distance.

In an example embodiment, the bond sites may include a bond site. located at a center area of the package substrate, that has a cross-sectional length longer than cross-sectional lengths of other bond sites disposed on a same line as the bond site located at the center area of the package substrate.

The foregoing and/or other features and utilities of the present general inventive concept may also be achieved by providing a method of forming bond sites on a package substrate that includes developing a pattern for the bond sites, the pattern including at least one bond site at a first distance in a first direction from a middle portion of the package substrate having a cross-sectional length that is longer than a cross-sectional length of at least one bond site at a second distance in the first direction from the middle portion, the first distance greater than the second distance, and forming the bond sites on the package substrate according to the pattern.

In an example embodiment, the pattern may have a radial form around the middle portion and the bond sites may be arranged within a range between zero and ninety degrees with respect to a horizontal plane.

In an example embodiment, the pattern may further include a bond site at a center area of the package substrate having a cross-sectional length that is longer than cross-sectional lengths of other bond sites disposed on a same line as the bond site located at the center area.

In an example embodiment, the method may further include forming a solder mask layer on the package substrate, the solder mask layer having openings formed at the bond sites.

In an example embodiment, the forming the bond sites may include forming bond sites, arranged in a second direction along the middle portion of the package substrate, that do not come into contact with the solder mask layer.

### BRIEF DESCRIPTION OF THE DRAWINGS

The foregoing and other features and utilities of the present general inventive concepts will become apparent and more readily appreciated from the following description of the embodiments, taken in conjunction with the accompanying drawings in which like reference characters refer to the same parts throughout the different views. The drawings are not necessarily to scale, emphasis instead being placed upon illustrating the principles of the present general inventive concept. In the drawings:

FIG. 1 is a cross-sectional view of a flip-chip semiconductor package according to an embodiment of the inventive concept;

FIG. 2 is a plan view of a package substrate applied to the flip-chip semiconductor package of FIG. 1;

FIGS. 3 and 4 are, respectively, a cross-sectional view and a plan view of a flip-chip bonding of a semiconductor chip to a package substrate in a flip-chip semiconductor package according to an embodiment of the inventive concept;

FIGS. 5A, 5B, and 5C are cross-sectional views taken, respectively, along lines ‘C,’ ‘I’ and ‘E’ of FIG. 4;

FIG. 6 is an enlarged view of a portion of a center area ‘C1’ of FIG. 5A;

FIG. 7 is an enlarged view of a portion of an intermediate area ‘I1’ of FIG. 5B;

FIG. 8 is an enlarged view of a portion of a center area ‘C2’ of FIG. 5A;

FIG. 9 is an enlarged view of a portion of an intermediate area ‘I2’ of FIG. 5B;

FIG. 10 is an enlarged view of a portion of an intermediate area ‘I3’ of FIG. 5B;

FIGS. 11A, 11B, and 11C are plan views of a conventional flip-chip semiconductor package;

FIGS. 12A, 12B, and 12C are plan views of a flip-chip semiconductor package according to an embodiment of the inventive concept;

FIG. 13 is a schematic view of a semiconductor module that has a flip-chip semiconductor package according to an embodiment of the inventive concept;

FIG. 14 is a block diagram schematically illustrating an electronic circuit board that includes a flip-chip semiconductor package according to an embodiment of the inventive concept;

FIG. 15 is a block diagram schematically illustrating an electronic system that includes a semiconductor module that has a flip-chip semiconductor package according to an embodiment of the inventive concept; and

FIG. 16 is a flowchart illustrating a method of forming bonding sites on a package substrate according to an embodiment of the inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It is understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It is understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of the present inventive concept.

Spatially relative terms, such as “beneath,” “below,” “lower,” “above,” “upper,” and the like, may be used herein for ease of description to describe one element's or feature's relationship to another element(s) or feature(s) as illustrated in the figures. It is understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

A conductive lead used herein may be referred to as a conductive trace, land, or pad as used in the art to which this inventive concept belongs, and it is understood that these terms are not intended to limit the scope of the present inventive concept.

Unless otherwise defined, all terms (including technical and scientific terms) used herein have the same meaning as commonly understood by one of ordinary skill in the art to which this inventive concept belongs. It is further understood that terms, such as those defined in commonly used dictionaries, should be interpreted as having a meaning that is consistent with their meaning in the context of the relevant art and not be interpreted in an idealized or overly formal sense unless expressly so defined herein.

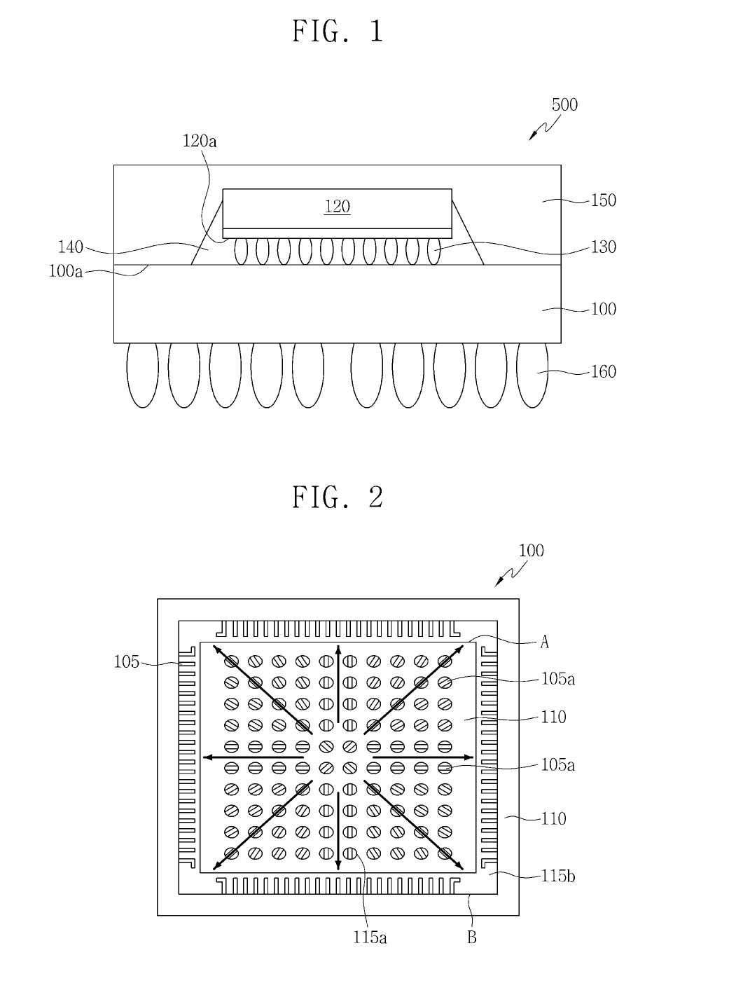

FIG. 1 is a cross-sectional view of a flip-chip semiconductor package 500 according to an embodiment of the inventive concept. FIG. 2 is a plan view of a package substrate 100 applied to the flip-chip semiconductor package 500 of FIG. 1.

Referring to FIGS. 1 and 2, the flip-chip semiconductor package 500 according to an embodiment of the inventive concept has a structure in which a semiconductor chip 120 may be directly mounted on a package substrate 100 through bumps 130.

The package substrate 100 may include, for example, a rigid printed circuit board, a flexible printed circuit board, a rigid-flexible printed circuit board, a ceramic board, or a glass board.

The package substrate 100 may include a plurality of conductive leads 105 formed on an upper surface thereof, that is, a chip attachment surface 100a. The conductive leads 105 may be electrically connected to conductive leads (not illustrated) formed at a lower surface (not illustrated) of the package substrate 100 through a plurality of metal interconnections (not illustrated) formed inside the package substrate 100. The conductive leads 105 may include, for example, copper (Cu), nickel (Ni), gold (Au), or a solder material. A ground voltage and a power voltage, for example, may be applied to the plurality of metal interconnections (not illustrated).

Each of the conductive leads 105 located on a chip mounting area ‘A’ of the package substrate 100, where the semiconductor chip 120 may be mounted, may have one of bond sites 105a. The bond sites 105a may be arranged in a radial form (see the arrows in FIG. 2) around a middle portion of the package substrate 100. For example, the bond sites 105a may be arranged at 0 degree and 90 degrees as well as within a range of between 0 and 90 degrees with respect to a horizontal plane.

The package substrate 100 may further include a solder mask layer 110 formed on the chip attachment surface 100a thereof. The solder mask layer 110 may have first openings 115a formed at the bond sites 105a. In addition, the solder mask layer 110 may have second openings 115b formed at a periphery ‘B’ of the chip mounting area A of the package substrate 100 to expose a portion of the conductive leads 105. Optionally, a solder paste (not illustrated) may be formed on surfaces of the bond sites 105a exposed through the first openings 115a.

The semiconductor chip 120 may include, for example, a semiconductor memory device, such as, for example, a dynamic random-access memory (DRAM), a static random-access memory (SRAM), a flash memory, a magnetoresistive random-access memory (MRAM), a ferroelectric random-access memory (FRAM), and a phase-change random-access memory (PRAM), a logic semiconductor device such as, for example, a microprocessor or a microcontroller, an optoelectronic device, or a communication device. In addition, the semiconductor chip 120 may be, for example, a system on chip (SOC) that has various types of semiconductor devices included in a single semiconductor chip.

The semiconductor chip 120 may further include chip pads (not illustrated) formed on an active surface 120a thereof. Each of the bumps 130 may be attached to a corresponding one of the chip pads on the active surface 120a of the semiconductor chip 120. The bump 130 may include, for example, a solder material or metal. In the case in which the bump 130 is a solder bump, the bump 130, after a solder reflow process, may be kept in a ball shape due to a surface tension effect. In the case in which the bump 130 is a metal bump, the bump 130 may be provided in the form of a mesa. The bump 130 may include, for example, gold (Au), silver (Ag), platinum (Ag), aluminum (Al), copper (Cu), or a solder material.

Each of the bumps 130 may be directly bonded to a corresponding one of the bond sites 105a on the conductive leads 105 formed on the chip mounting area A of the package substrate 100. The bump 130 may come into contact with a sidewall (not illustrated) of the bond site 105a. Alternatively, the bump 130 may be formed to come into contact with a portion of an upper surface (not illustrated) of the bond site 105a without coming into contact with a sidewall of the bond site 105a.

The flip-chip semiconductor package 500 may further include a molding member 140 to fill up a space between the active surface 120a of the semiconductor chip 120 and the package substrate 100. The molding member 140 may protect the bumps 130 attached to the active surface 120a of the semiconductor chip 120 while also relieving the stress acting on the chip attachment surface 100a of the package substrate 100. The molding member 140 may be formed, for example, of an underfill resin such as an epoxy resin, and may include, for example, a silica filler or a silica plus.

The flip-chip semiconductor package 500 may include an encapsulant 150, to seal the semiconductor chip 120 mounted on the package substrate 100, and external connection members 160, to electrically connect the flip-chip semiconductor package 500 to a semiconductor module board (not illustrated) or a system board (not illustrated) while being formed at a lower surface of the package substrate 100.

The external connection member 160 may be formed, for example, of a solder material, such as a solder ball, a solder bump, and a solder paste, or formed, for example, of a metal in a shape having a sphericity, a shape of a mesa, or a shape of a pin. The external connection members 160 may be arranged, for example, in a grid type to implement a ball grid array (BGA) package.

The encapsulant 150 may include, for example, an epoxy resin or an epoxy mold compound (EMC). Optionally, the encapsulant 150 may be formed at the lower surface of the package substrate 100 to stably support the external connection members 160.

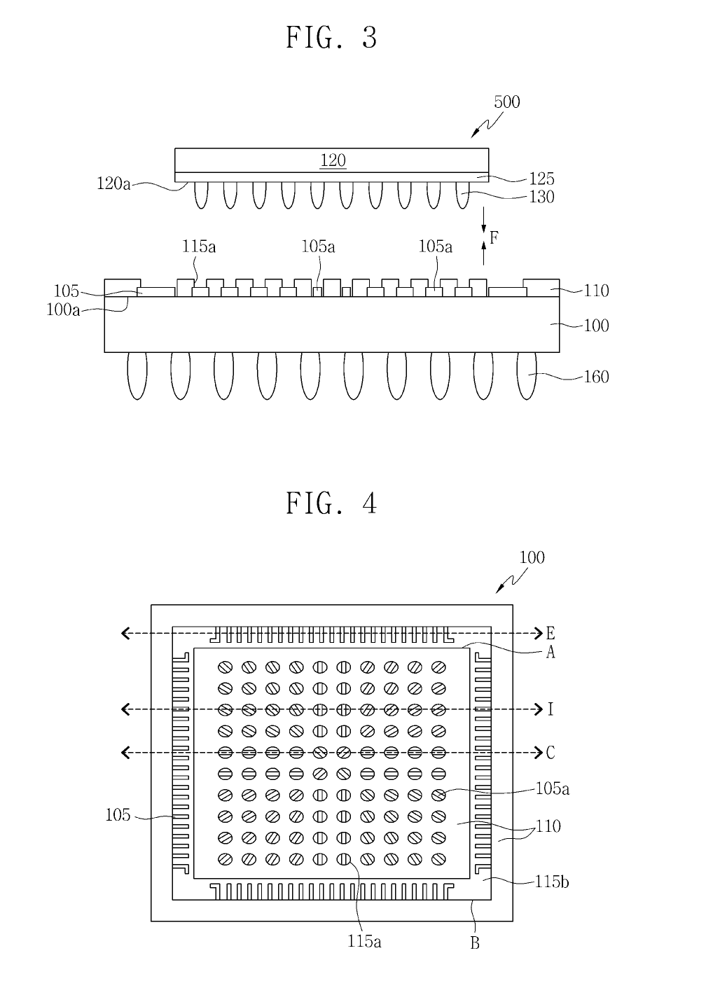

FIGS. 3 and 4 are, respectively, a cross-sectional view and a plan view of a flip-chip bonding of the semiconductor chip 120 to the package substrate 100 in the flip-chip semiconductor package 500 according to an embodiment of the inventive concept.

Referring to FIGS. 3 and 4, there may be provided the package substrate 100, having the bond sites 105a formed at the chip attachment surface 100a thereof, and the semiconductor chip 120 having a circuit area 125.

A plurality of conductive leads 105 may be formed on an upper surface of the package substrate 100, that is, the chip attachment surface 100a. Each of the conductive leads 105 may have one of the bond sites 105a at the chip mounting area A for the semiconductor chip 120. The bond sites 105a may be arranged in a radial form around a middle portion of the package substrate 100. For example, the bond sites 105a may be arranged at 0 degree and 90 degrees as well as within a range of between 0 and 90 degrees with respect to a horizontal plane.

The solder mask layer 110 may be formed on the chip attachment surface 100a of the package substrate 100. The solder mask layer 110 may have the first openings 115a formed at the bond sites 105a. In addition, the solder mask layer 110 may have the second openings 115b formed at the periphery B of the chip mounting area A of the package substrate 100 to expose a portion of the conductive leads 105. Optionally, a solder paste may be formed on surfaces of the bond sites 105a exposed through the first openings 115a.

The bumps 130 may be attached to the chip pads (not illustrated) formed on the active surface 120a of the semiconductor chip 120. As the semiconductor chip 120 is bonded to the package substrate 100 through the bumps 130 in a direction of arrows ‘F’ illustrated in FIG. 3, the flip-chip semiconductor package 500 may be formed.

Each of the bumps 130 may be directly bonded to a corresponding one of the bond sites 105a on the conductive leads 105 of the package substrate 100. The bump 130 may make contact with a sidewall of the bond site 105a. Alternatively, the bump 130 may be formed to come into contact with a portion of an upper surface of the bond site 105a without coming into contact with a sidewall of the bond site 105a.

The chip attachment surface 100a of the package substrate 100 may be divided into a center area ‘C’ of the chip mounting area A, an edge area ‘E’ located at the periphery B of the chip mounting area A and an intermediate area ‘1’ between the center area C and the edge area E.

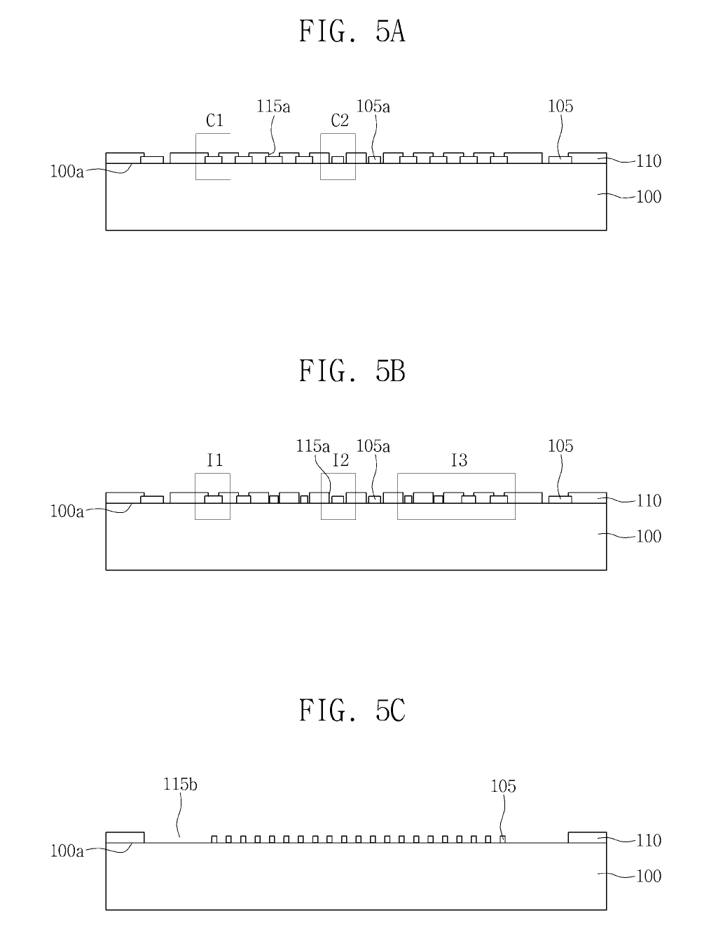

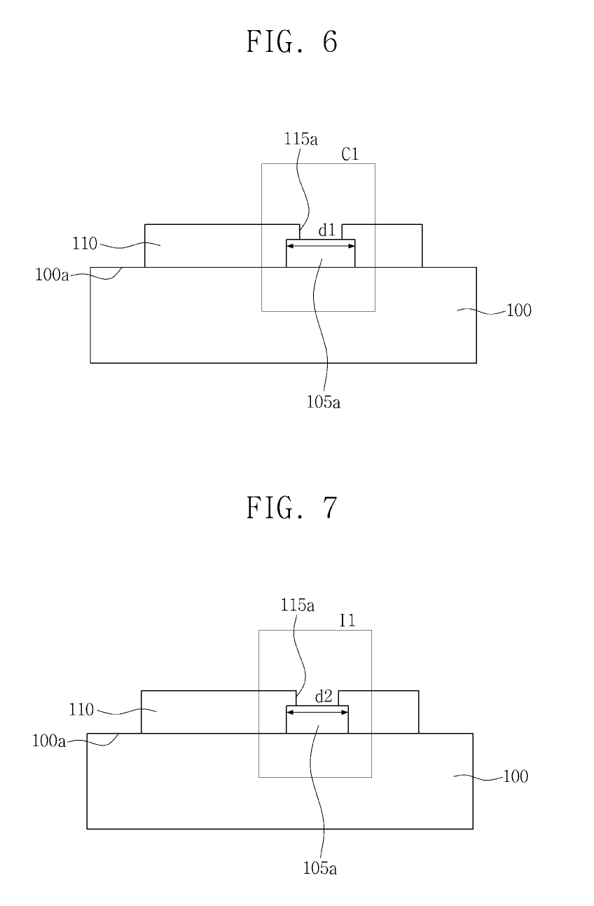

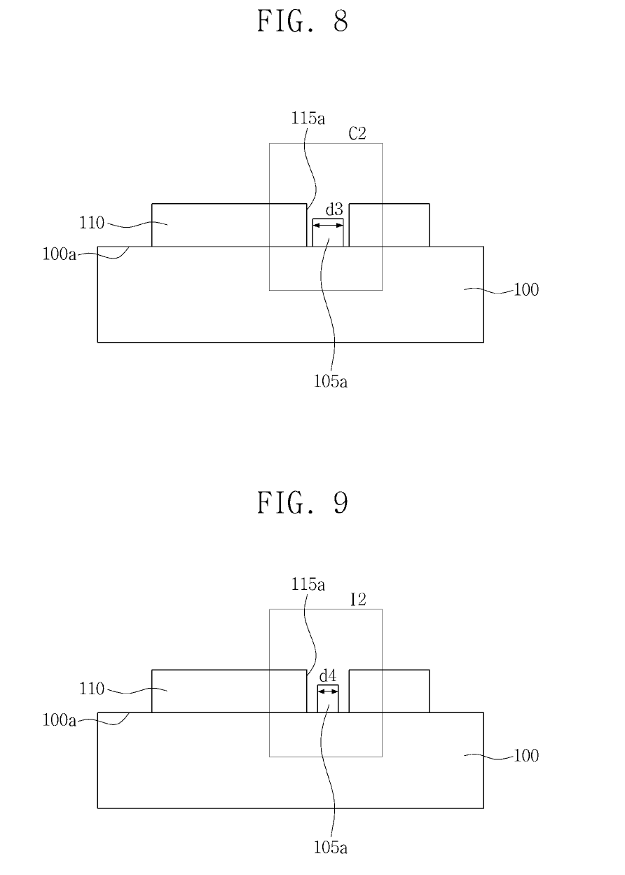

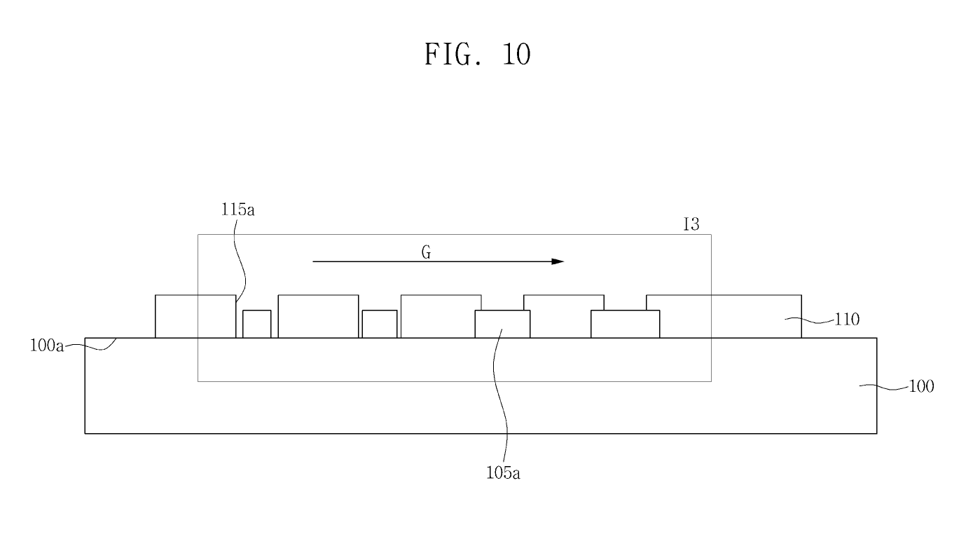

FIGS. 5A, 5B, and 5C are cross-sectional views taken, respectively, along lines C, I, and E of FIG. 4. FIG. 6 is an enlarged view of a portion of a center area ‘C1’ of FIG. 5A. FIG. 7 is an enlarged view of a portion of an intermediate area ‘I1’ of FIG. 5B. FIG. 8 is an enlarged view of a portion of a center area ‘C2’ of FIG. 5A. FIG. 9 is an enlarged view of a portion of an intermediate area ‘I2’ of FIG. 5B. FIG. 10 is an enlarged view of a portion of an intermediate area ‘I3’ of FIG. 5B.

Referring to FIGS. 5A to 5C and FIGS. 6 to 10, the bond site 105a located at a middle portion of the package substrate 100 may not come into contact with the solder mask layer 110 (see center area C2 of FIG. 5A).

The bond sites 105a located at the center areas C1 and C2 (see FIG. 5A) of the package substrate 100 may have, respectively, cross-sectional lengths d1 (see FIG. 6) and d3 (see FIG. 8) larger than cross-sectional lengths d2 (see FIGS. 7) and d4 (see FIG. 9) of other bond sites 105a located on a same line as the bond sites 105a at the center areas C1 and C2.

The bond sites 105a arranged in a vertical direction at the middle portion of the package substrate 100 may not come into contact with the solder mask layer 110 (see intermediate area I2 of FIG. 5B).

As distance in a horizontal direction from the middle portion of the package substrate 100 increases (that is, in a direction of an arrow G illustrated in FIG. 10, so may a cross-sectional length of a corresponding of the bond sites 105a with respect to a cross-sectional length of a bond site 105a at a closer distance in the horizontal direction from the middle portion of the package substrate 100.

The semiconductor chip 120 may be mounted on the package substrate 100, on which the bond sites 105a having the above described cross-sectional structure may be formed, through the bumps 130. In order to protect electrical connections between the semiconductor chip 120 and the bumps 130, a molding member 140 (see FIG. 1) may be filled between the semiconductor chip 120 and the chip attachment surface 100a of the package substrate 100. The molding member 140 may be formed, for example, by an underfill process using a capillary phenomenon. For example, a liquid film formed of a resin-based material may be inserted between the semiconductor chip 120 and the chip attachment surface 100a of the package substrate 100, and a thermal compression process or a reflow process may be performed on the semiconductor chip 120 and the package substrate 100. During such a thermal compression process or a reflow process, the liquid film may be completely cured, so that the thermal or mechanical stress applied to the semiconductor chip 120 and the bumps 130 may be relieved.

The encapsulant 150 (see FIG. 1) may be formed on the package substrate 100 while surrounding the semiconductor chip 120. The encapsulant 150 may include, for example, an epoxy resin or an epoxy-based composite (EMC).

The external connection members 160 may be formed at the lower surface of the package substrate 100 to electrically connect the flip-chip semiconductor package 500 to the semiconductor module board (not illustrated) or the system board (not illustrated). The external connection members 160 may be formed, for example, of a solder material such as a solder ball, a solder bump, and a solder paste, or formed, for example, of metal in a shape having a sphericity, a shape of a mesa, or a shape of a pin. The external connection members 160 may be arranged, for example, in a grid type to implement a ball grid array (BGA) package.

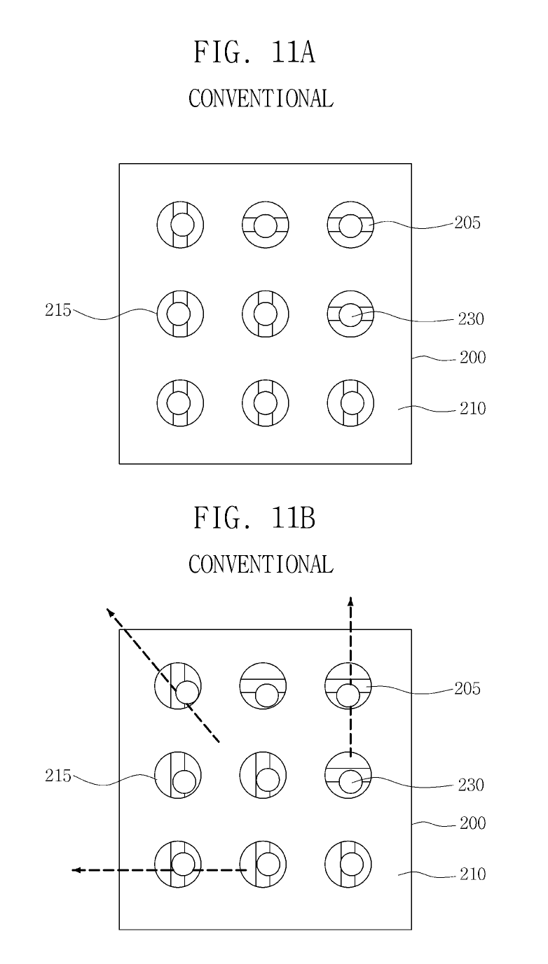

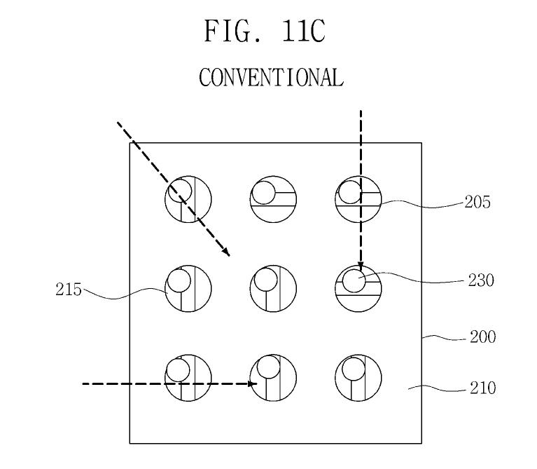

FIGS. 11A, 11B, and 11C are plan views of a conventional flip-chip semiconductor package.

Referring to FIG. 11A, a conventional flip-chip semiconductor package has bond sites 205 arranged at an angle of 0 degree and an angle of 90 degrees on a chip attachment surface of a package substrate 200. If the package substrate 200 includes a solder mask layer, the solder mask layer may have openings 215 formed at the bond sites 205.

When a solder reflow process is performed to interconnect the bumps 230 to the bond sites 205, which are perpendicularly arranged at angles of 0 degree and 90 degrees as the above, the package substrate 200 is thermally expanded in the directions of the arrows illustrated in FIG. 11B. After the solder reflow process is completed, the package substrate 200 is shrunk in the directions of the arrows illustrated in FIG. 11C, which may result in or lead to physical deviations of the bumps 230 from the positions of the bond sites 205.

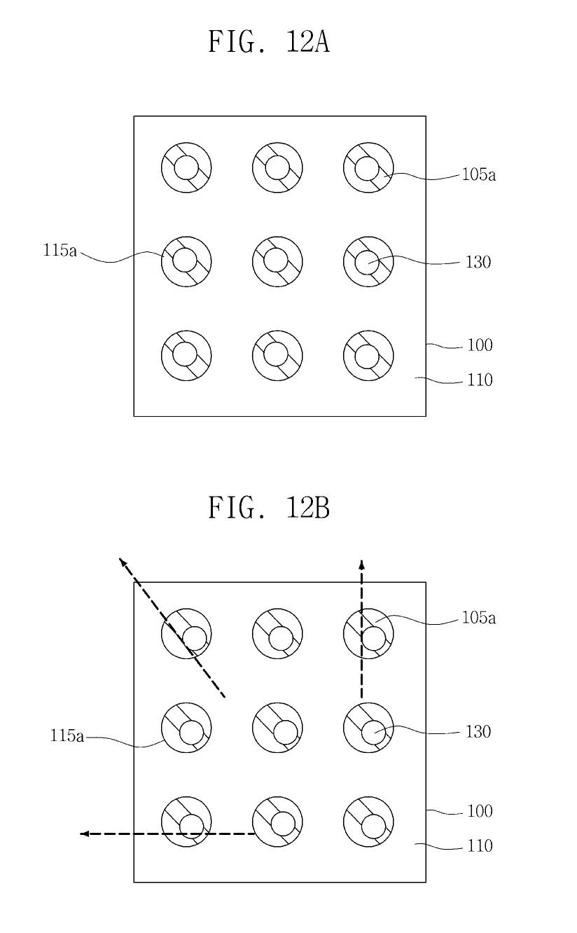

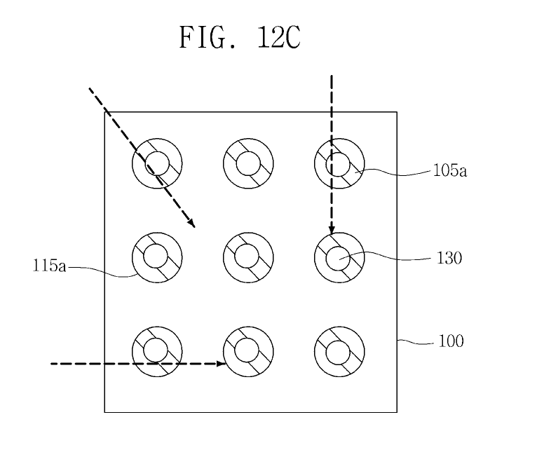

FIGS. 12A, 12B, and 12C are plan views of a flip-chip semiconductor package according to an embodiment of the inventive concept.

Referring to FIG. 12A, the flip-chip semiconductor package according to the inventive concept may have the bond sites 105a formed at the chip attachment surface of the package substrate 100 to be arranged in a radial form around the middle portion of the package substrate 100. If the package substrate 100 includes a solder mask layer, the solder mask layer may have first openings 115a formed at the bond sites 105a.

When a solder reflow process is performed to interconnect the bumps 130, which are attached to the active surface of the semiconductor chip, to the bond sites 105a of the package substrate 100, the package substrate 100 may be thermally expanded in the directions of the arrows illustrated in FIG. 12B. After the solder reflow process is completed, the package substrate 100 may be shrunk in the directions of the arrows illustrated in FIG. 12C.

Since the bond sites 105a on the package substrate 100 are radially arranged in directions coincident with the thermal expansion directions of the package substrate 100, the bumps 130 do not deviate from the bond sites 105a even after the package substrate 100 is shrunk.

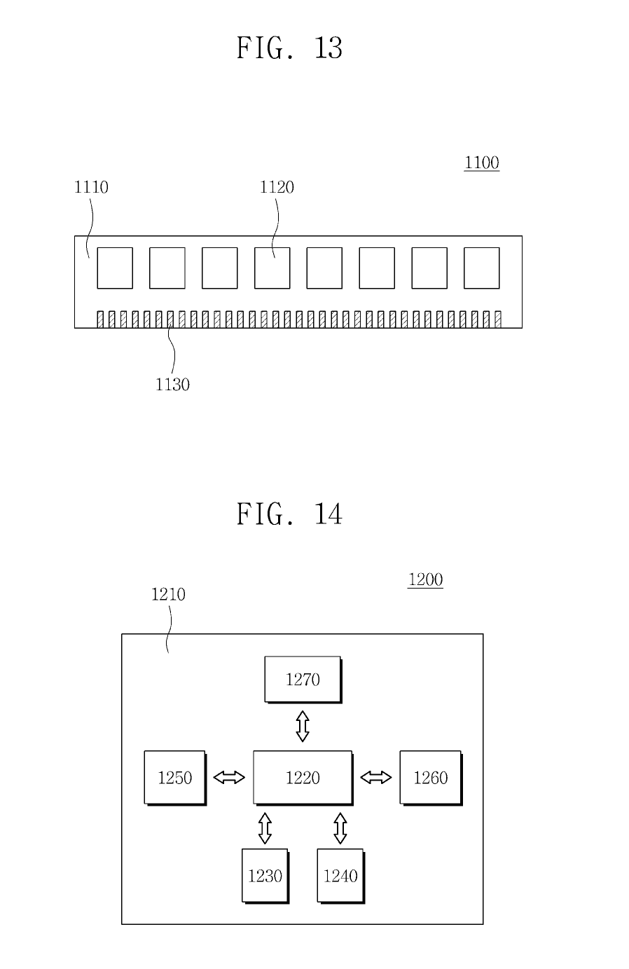

FIG. 13 is a schematic view of a semiconductor module 1100 that has a flip-chip semiconductor package according to an embodiment of the inventive concept.

Referring to FIG. 13, the semiconductor module 1100 that has a package structure according to an embodiment of the inventive concept mounted thereon may include a module substrate 1110, a plurality of semiconductor devices or flip-chip semiconductor packages 1120 being disposed on the module substrate 1110, and module contact terminals 1130 formed side by side on one edge of the module substrate 1110 and electrically connected, respectively, to the semiconductor devices or flip-chip semiconductor packages 1120.

The module substrate 1110 may be, for example, a printed circuit board (PCB). Both surfaces of the module substrate 1110 may be available for use. That is, the semiconductor devices or flip-chip semiconductor packages 1120 may be disposed at both of a front surface and a rear surface of the module substrate 1110.

The semiconductor module 1100 may further include, for example, an additional controller (not illustrated) or a chip set (not illustrated) so as to control the semiconductor devices or flip-chip semiconductor packages 1120.

For example, the module contact terminals 1130 may be formed of a metal, and may have oxidation resistance. The module contact terminals 1130 may be variously set and conform to the standards of the semiconductor module 1100.

FIG. 14 is a block diagram schematically that illustrates an electronic circuit board 1200 that includes a flip-chip semiconductor package according to an embodiment of the inventive concept.

Referring to FIG. 14, the electronic circuit board 1200 according to an embodiment of the inventive concept may include a microprocessor 1220 disposed on a circuit board 1210, a main storage circuit 1230 and a supplementary storage circuit 1240 that communicate with the microprocessor 1220, an input signal processing circuit 1250 that transmits a command to the microprocessor 1220, an output signal processing circuit 1260 that receives a command from the microprocessor 1220, and a communication signal processing circuit 1270 that transmits and receives an electrical signal to/from other circuits. Arrows illustrated in FIG. 14 may be understood as paths that deliver electrical signals.

The microprocessor 1220 may receive various electrical signals and may process the received electrical signals to output a result of the processing, and may control other component of the electronic circuit board 1200. The microprocessor 1220, for example, may be understood as a central processing unit (CPU) and/or a main control unit (MCU).

The main storage circuit 1230 may temporarily store data that is frequently required by the microprocessor 1220 or data obtained before and/or after the processing. The main storage circuit 1230, which may require a high speed response, may be formed as a semiconductor memory device. For example, the main storage circuit 1230 may be a semiconductor memory device, called ‘a cache’, a static random access memory (SRAM), a dynamic random access memory (DRAM), a resistive random access memory (RRAM), and/or an applied semiconductor device thereof, e.g., a utilized RAM, a ferro-electric RAM, a fast cycle RAM, a phase changeable RAM, and/or a magnetic RAM, and/or other semiconductor memory devices. The semiconductor memory device may be included in various types of flip-chip semiconductor packages according to the inventive concept. In addition, the main storage circuit 1230 may include a volatile or non-volatile random access memory. In this embodiment, the main storage circuit 1230 may include the semiconductor module 1100 that has the flip-chip semiconductor packages according to the inventive concept.

The supplementary storage circuit 1240 may be a large capacity memory device, and may be a non-volatile semiconductor memory, such as, for example, a flash memory, or a hard disk drive that uses a magnetic field. Alternatively, the supplementary storage circuit 1240 may be a compact disk drive that uses light. The supplementary storage circuit 1240 that has a large storage capacity may be more important than the supplementary storage circuit 1240 that has a speed greater than that of the main storage circuit 1230. The supplementary storage circuit 1240 may include the semiconductor module 1100 that has the flip-chip semiconductor packages according to the inventive concept.

The input signal processing circuit 1250 may convert a command from an outside component into an electrical signal, or may transmit an electrical signal delivered from the outside component to the microprocessor 1220. The command or electrical signal delivered from the outside component may be a command for operation, an electrical signal to be processed, or data to be stored. The input signal processing circuit 1250 may be, for example, a terminal signal processing circuit configured to process a signal that is transmitted from, for example, a keyboard, a mouse, a touch pad, an image recognition device, and/or various sensors, an image signal processing circuit configured to process an image signal of, for example, a scanner and/or a camera, various types of sensors, and/or an input signal interface. The input signal processing circuit 1250 may include the semiconductor module 1100 that has the flip-chip semiconductor packages according to the inventive concept.

The output signal processing circuit 1260 may be a component configured to transmit an electric signal, which has been processed by the microprocessor 1220, to an outside component. For example, the output signal processing circuit 1260 may be a graphic card, an image processor, an optical transducer, a beam panel card, and/or an interface circuit that has various functions. The output signal processing circuit 1260 may include the semiconductor module 1100 that has the flip-chip semiconductor packages according to the inventive concept.

The communication signal processing circuit 1270 may be a component configured to directly transmit and/or receive an electrical signal to/from another electronic system or another circuit board without passing through the input signal processing circuit 1250 or the output signal processing circuit 1260. For example, the communication signal processing circuit 1270 may be a modem, a local area network (LAN) card, and/or various interface circuits of a personal computer system. The communication signal processing circuit 1270 may include the semiconductor module 1100 that has the flip-chip semiconductor packages according to the inventive concept.

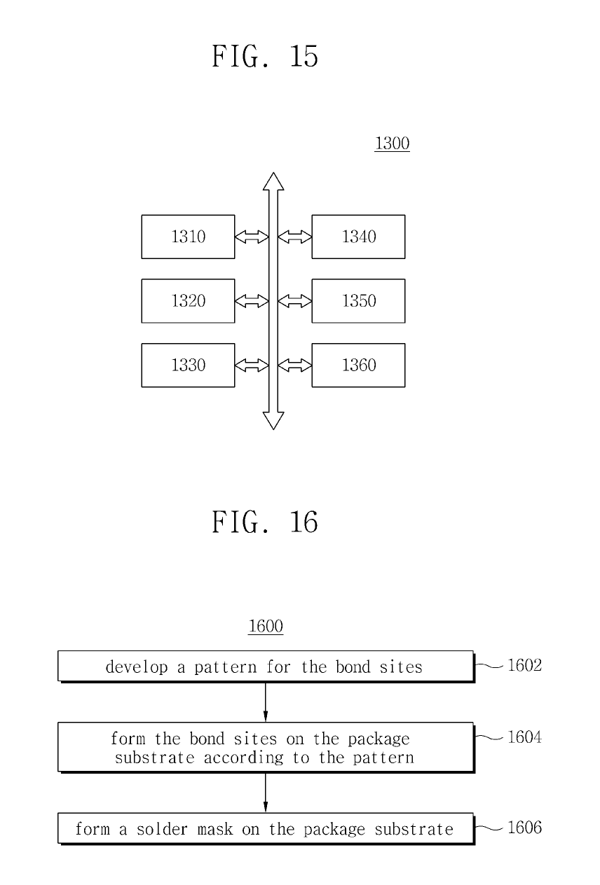

FIG. 15 is a block diagram that schematically illustrates an electronic system 1300 that includes the semiconductor module 100 that has a flip-chip semiconductor package according to an embodiment of the inventive concept.

Referring to FIG. 15, the electronic system 1300 according to the inventive concept may include a control unit 1310, an input unit 1320, an output unit 1330, and a storage unit 1340, and may further include a communication unit 1350 and/or an operation unit 1360.

The control unit 1310 may control the overall operation of the electronic system 1300 and the respective parts of the electronic system 1300. The control unit 1310 may be understood as a central processing unit or a central control unit, and may include the electronic circuit board 1200 according to the inventive concept. In addition, the control unit 1310 may include the semiconductor module 1100 that has the flip-chip semiconductor packages according to the inventive concept.

The input unit 1320 may transmit an electrical command signal to the control unit 1310. The input unit 1320 may be, for example, a keyboard, a keypad, a mouse, a touch pad, an image recognizing device, such as a scanner, and/or various input sensors. The input unit 1320 may include the semiconductor module 1100 that has the flip-chip semiconductor packages according to the inventive concept.

The output unit 1330 may receive an electrical command signal from the control unit 1310 to output a result processed by the electronic system 1300. The output unit 1330 may be, for example, a monitor, a printer, a beam exposer, and/or various mechanical devices. The output unit 1330 may include the semiconductor module 1100 that has the flip-chip semiconductor packages according to the inventive concept.

The storage unit 1340 may be a component to temporarily or permanently store an electrical signal that is to be processed or has been processed by the control unit 1310. The storage unit 1340 may be physically or electrically connected or coupled to the control unit 1310. The storage unit 1340 may be, for example, a semiconductor memory, a magnetic storage device such as a hard disc, an optical storage device such as a compact disc, and/or a server that has data storage functions. In addition, the storage unit 1340 may include the semiconductor module 1100 that has the flip-chip semiconductor packages according to the inventive concept.

The communication unit 1350 may receive an electrical command signal from the control unit 1310 to transmit and/or receive an electrical signal to/from another electronic system. The communication unit 1350 may be, for example, a wired transmission/reception device such as a modem and/or a LAN card, a wireless transmission/reception device such as a WIBRO interface, and/or an infrared port. In addition, the communication unit 1350 may include the semiconductor module 1100 that has the flip-chip semiconductor packages according to the inventive concept.

The operation unit 1360 may perform a physical and/or mechanical operation according to a command of the control unit 1310. For example, the operation unit 1360 may be a component, for example, a plotter, an indicator, and an up/down operator, to perform a mechanical operation. The electronic system 1300 according to the inventive concept may be, for example, a computer, a network server, and/or a networking printer, and/or a scanner, a wireless controller, a mobile communication-purpose terminal, and/or a switching apparatus, and/or another electronic product configured to perform a programed operation.

FIG. 16 is a flowchart that illustrates a method 1600 of forming bonding sites on a package substrate according to an embodiment of the inventive concept.

In an operation 1602 of the method 1600, a pattern for the bonding sites may be developed. The pattern may include at least one bond site at a first distance in a first direction from a middle portion of the package substrate that has a cross-sectional length that is longer than a cross-sectional length of at least one bond site at a second distance in the first direction from the middle portion. The first distance may be greater than the second distance. Optionally, the pattern may have a radial form around the middle portion and the bond sites may be arranged within a range between zero and ninety degrees with respect to a horizontal plane. Optionally, the pattern may further include a bond site at a center area of the package substrate that has a cross-sectional length that is longer than cross-sectional lengths of other bond sites disposed on a same line as the bond site located at the center area of the package substrate.

In an operation 1604 of the method 1600, the bond sites on the package substrate may be formed according to the pattern.

Optionally, in an operation 1606 of the method 1600, a solder mask layer on the package substrate may be formed. The solder mask layer may have openings formed at the bond sites.

Optionally, the forming the bond sites may include forming bond sites, arranged in a second direction along the middle portion of the package substrate, that do not come into contact with the solder mask layer.

As may be seen from the foregoing, the bond sites 105a on the chip attachment surface 100a of the package substrate 100, to which the semiconductor chip 120 may be flip-chip bonded through the bumps 130, may be arranged in a radial form, thereby preventing the bumps 130 from being physically deviated from the bond sites 105a due to the thermal expansion and/or shrinkage of the package substrate 100.

The foregoing is illustrative of embodiments and is not to be construed as limiting thereof. Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A flip-chip semiconductor package, comprising:
a semiconductor chip;
a package substrate having a chip attachment surface on which bond sites are formed; and
bumps attached to an active surface of the semiconductor chip and bonded to the bond sites,
wherein the bond sites are radially arranged around a middle portion of the package substrate.

2. The flip-chip semiconductor package according to claim 1, further comprising conductive leads formed on the chip attachment surface of the package substrate,
wherein the bond sites exist on the conductive leads.

3. The flip-chip semiconductor package according to claim 1, further comprising a solder mask layer formed on the chip attachment surface of the package substrate,
wherein the solder mask layer has openings formed at the bond sites.

4. The flip-chip semiconductor package according to claim 3, wherein the bond sites include a bond site, disposed at the middle portion of the package substrate, that does not come into contact with the solder mask layer.

5. The flip-chip semiconductor package according to claim 3, wherein the bond sites include bond sites, arranged in a vertical direction along the middle portion of the package substrate, that do not come into contact with the solder mask layer.

6. The flip-chip semiconductor package according to claim 1, wherein a cross-sectional length of each bond site at a first distance in a horizontal direction from the middle portion is longer than a cross-sectional length of each bond site at a second distance in the horizontal direction from the middle portion, the first distance greater than the second distance.

7. The flip-chip semiconductor package according to claim 1, wherein the bond sites include a bond site, located at a center area of the package substrate, that has a cross-sectional length longer than cross-sectional lengths of other bond sites disposed on a same line as the bond site located at the center area of the package substrate.

8. The flip-chip semiconductor package according to claim 1, wherein at least one of the bumps is in contact with a sidewall of the bond site.

9. The flip-chip semiconductor package according to claim 1, wherein at least one of the bumps is in contact with an upper surface of the bond site except for a sidewall of the bond site.

10. A package substrate, comprising bond sites formed on a chip attachment surface thereof,
wherein the bond sites are radially arranged around a middle portion of the package substrate.

11. The package substrate according to claim 10, further comprising conductive leads formed on the chip attachment surface of the package substrate,
wherein the bond sites exist on the conductive leads.

12. The package substrate according to claim 10, further comprising a solder mask layer formed on the chip attachment surface of the package substrate,
wherein the solder mask layer has openings formed at the bond sites.

13. The package substrate according to claim 12, wherein the bond sites include bond sites, arranged in a vertical direction along the middle portion of the package substrate, that do not come into contact with the solder mask layer.

14. The package substrate according to claim 10, wherein a cross-sectional length of each bond site at a first distance in a horizontal direction from the middle portion is longer than a cross-sectional length of each bond site at a second distance in the horizontal direction from the middle portion, the first distance greater than the second distance.

15. The package substrate according to claim 10, wherein the bond sites include a bond site located at a center area of the package substrate, that has a cross-sectional length longer than cross-sectional lengths of other bond sites disposed on a same line as the bond site located at the center area of the package substrate.

16. A method of forming bond sites on a package substrate, the method comprising:
developing a pattern for the bond sites, the pattern including at least one bond site at a first distance in a first direction from a middle portion of the package substrate having a cross-sectional length that is longer than a cross-sectional length of at least one bond site at a second distance in the first direction from the middle portion, the first distance greater than the second distance; and
forming the bond sites on the package substrate according to the pattern.

17. The method of claim 16, wherein the pattern has a radial form around the middle portion and the bond sites are arranged within a range between zero and ninety degrees with respect to a horizontal plane.

18. The method of claim 16, wherein the pattern further includes a bond site at a center area of the package substrate having a cross-sectional length that is longer than cross-sectional lengths of other bond sites disposed on a same line as the bond site located at the center area.

19. The method of claim 16, further comprising forming a solder mask layer on the package substrate, the solder mask layer having openings formed at the bond sites.

20. The method of claim 19, wherein the forming the bond sites includes forming bond sites, arranged in a second direction along the middle portion of the package substrate, that do not come into contact with the solder mask layer.
